(19) United States
(12) Patent Application Publication
(10) Pub. No.: US 2025/0391367 A1
(43) Pub. Date: Dec. 25, 2025

(54) PIXEL CIRCUIT, DISPLAY DEVICE AND ELECTRONIC DEVICE INCLUDING THE SAME

(71) Applicant: Samsung Display Co., Ltd., Yongin-si (KR)

(72) Inventors: Keunwoo Kim, Yongin-si (KR); Sangsub Kim, Yongin-si (KR); Hyoungdo Kim, Yongin-si (KR); Bummo Sung, Yongin-si (KR); Hyelim Choi, Yongin-si (KR)

(21) Appl. No.: 19/247,663

(22) Filed: Jun. 24, 2025

(30) Foreign Application Priority Data
Jun. 25, 2024 (KR) 10-2024-0083030

(51) Int. Cl. G09G 3/3233

(52) U.S. Cl. CPC G09G 3/3233; G09G 2300/0819; G09G 2310/08; G09G 2330/021

(57) ABSTRACT

A pixel circuit includes: a light-emitting element; a first switching element configured to control a driving current flowing through the light-emitting element and including an upper gate electrode, a lower gate electrode, and a semiconductor layer between the upper gate electrode and the lower gate electrode in a cross-sectional view of the pixel circuit; a second switching element electrically connected to the lower gate electrode and configured to transmit a data signal to the lower gate electrode based on a data control signal; and a storage capacitor including a first electrode electrically connected to the lower gate electrode and a second electrode electrically connected to one of source-drain electrodes of the first switching element.

### CROSS-REFERENCE TO RELATED APPLICATION

The present application claims priority to and the benefit of Korean Patent Application No. 10-2024-0083030, filed on Jun. 25, 2024, in the Korean Intellectual Property Office, the entire disclosure of which is incorporated herein by reference.

### BACKGROUND

### 1 Field

Aspects of some embodiments relate to a pixel circuit and a display device including the pixel circuit.

### 2 Description of the Related Art

A display device receives information about an image and displays the image. Display devices may be used as display units for small products such as mobile phones or for large products such as televisions.

A display device includes a plurality of pixels that emit light by receiving electrical signals to externally display images. Each pixel includes a light-emitting element. For example, in a case of an organic light-emitting display device, each pixel includes an organic light-emitting diode as the light-emitting element. In general, in an organic light-emitting display device, thin-film transistors and organic light-emitting diodes are formed on a substrate, and the organic light-emitting diodes operate by emitting light by themselves.

The above information disclosed in this Background section is only for enhancement of understanding of the background and therefore the information discussed in this Background section does not necessarily constitute prior art.

### SUMMARY

Aspects of some embodiments relate to a pixel circuit, a display device including the pixel circuit and an electronic device, and for example, to the pixel circuit for implementing a high-resolution screen, a display device including the pixel circuit and an electronic device.

Aspects of some embodiments include a pixel circuit for implementing a high-resolution screen, a display device including the pixel circuit and an electronic device. However, these characteristics are just examples, and the scope of embodiments according to the present disclosure is not limited thereto.

Additional aspects will be set forth in part in the description which follows and, in part, will be more apparent from the description, or may be learned by practice of the embodiments of the present disclosure.

According to some embodiments of the present disclosure, a pixel circuit includes a light-emitting element, a first switching element configured to control a driving current flowing through the light-emitting element and including an upper gate electrode, a lower gate electrode, and a semiconductor layer between the upper gate electrode and the lower gate electrode in a cross-sectional view of the pixel circuit, a second switching element electrically connected to the lower gate electrode and configured to transmit a data signal to the lower gate electrode based on a data control signal, and a storage capacitor including a first electrode electrically connected to the lower gate electrode and a second electrode electrically connected to one of source-drain electrodes of the first switching element.

According to some embodiments, the first switching element may be turned on or off based on an emission control signal transmitted through the upper gate electrode.

According to some embodiments, a magnitude of the driving current may correspond to the data signal transmitted through the lower gate electrode.

According to some embodiments, the pixel circuit may further include a third switching element electrically connected between the first electrode and a reference voltage line configured to transmit a reference voltage.

According to some embodiments, the light-emitting element may include an anode electrode electrically connected to the first switching element, and the pixel circuit may further include a fourth switching element electrically connected between the anode electrode and an initialization voltage line configured to transmit an initialization voltage.

According to some embodiments, the light-emitting element may include the anode electrode electrically connected to the first switching element, and the pixel circuit may further include a fifth switching element electrically connected between the anode electrode and the first switching element.

According to some embodiments, the semiconductor layer of the first switching element may include an oxide semiconductor.

According to some embodiments, the semiconductor layer of the fifth switching element may include low-temperature polysilicon.

According to some embodiments, the first electrode may be a portion of the lower gate electrode.

According to some embodiments, the second electrode may be a portion of the semiconductor layer of the fifth switching element.

According to some embodiments, the portion of the lower gate electrode and the portion of the semiconductor layer of the fifth switching element may overlap in a plan view of the pixel circuit.

According to some embodiments, the portion of the semiconductor layer of the fifth switching element may be electrically connected to one of the source-drain electrodes of the first switching element.

According to some embodiments, the other one of the source-drain electrodes of the first switching element may be electrically connected to a power voltage line transmitting a power voltage.

According to some embodiments, a first distance between an upper surface of the semiconductor layer of the first switching element and the upper gate electrode may be smaller than a second distance between a lower surface of the semiconductor layer of the first switching element and the lower gate electrode.

According to some embodiments, a display device includes a pixel circuit including a light-emitting element that emits light according to a data signal and a gate control signal, a gate driver configured to generate the gate control signal, a data driver configured to generate the data signal, and a controller configured to control the gate driver and the data driver. According to some embodiments, the pixel circuit may include a first switching element configured to control a driving current flowing through the light-emitting element and including an upper gate electrode, a lower gate electrode, and a semiconductor layer between the upper gate electrode and the lower gate electrode in a cross-sectional view of the pixel circuit, a second switching element electrically connected to the lower gate electrode and configured to transmit the data signal to the lower gate electrode based on a data control signal, and a storage capacitor including a first electrode electrically connected to the lower gate electrode and a second electrode electrically connected to one of source-drain electrodes of the first switching element.

According to some embodiments, the first switching element may be turned on or off based on an emission control signal transmitted through the upper gate electrode.

According to some embodiments, a magnitude of the driving current may correspond to the data signal transmitted through the lower gate electrode.

According to some embodiments, the light-emitting element may include an anode electrode electrically connected to the first switching element, and the pixel circuit may further include a fifth switching element electrically connected between the anode electrode and the first switching element.

According to some embodiments, the first electrode may be a portion of the lower gate electrode.

According to some embodiments, the second electrode may be a portion of the semiconductor layer of the fifth switching element.

According to some embodiments of the present disclosure, an electronic device comprises a memory which stores data information, a processor which generates data signals and/or control signals based on the data information, and a display device which operates based on the data signals and/or the control signals, wherein the display device comprises a pixel circuit including a light-emitting element configured to emit light according to a data signal and a gate control signal, a gate driver configured to generate the gate control signal, a data driver configured to generate the data signal, and a controller configured to control the gate driver and the data driver, wherein the pixel circuit includes a first switching element configured to control a driving current flowing through the light-emitting element and including an upper gate electrode, a lower gate electrode, and a semiconductor layer between the upper gate electrode and the lower gate electrode in a cross-sectional view of the pixel circuit, a second switching element electrically connected to the lower gate electrode and configured to transmit the data signal to the lower gate electrode based on a data control signal, and a storage capacitor including a first electrode electrically connected to the lower gate electrode and a second electrode electrically connected to one of source-drain electrodes of the first switching element.

The pixel circuit can achieve the effect of an ultra-high resolution display device.

### BRIEF DESCRIPTION OF THE DRAWINGS

The above and other aspects, features, and characteristics of certain embodiments of the disclosure will be more apparent from the following description taken in conjunction with the accompanying drawings, in which:

FIG. 1 is a conceptual diagram schematically illustrating a display panel of a display device according to some embodiments;

FIG. 2 is a plan view schematically illustrating the display panel according to some embodiments;

FIG. 3 is a cross-sectional view schematically illustrating a portion of the display device of FIG. 1;

FIG. 4 is an example of an equivalent circuit diagram schematically illustrating a pixel circuit of the display panel of FIG. 1;

FIG. 5 is a timing diagram illustrating control signals transmitted to each of switching elements of the pixel circuit of FIG. 4;

FIG. 6 is another example of the equivalent circuit diagram schematically illustrating a pixel circuit of the display panel of FIG. 1;

FIG. 7 is a cross-sectional view schematically illustrating an example of a thin-film transistor having a dual-gate structure; and

FIG. 8 is an example of an equivalent circuit diagram schematically illustrating a pixel circuit of a display panel according to a comparative example.

FIG. 9 is a block diagram of an electronic device.

FIG. 10 shows schematic views of various electronic device.

### DETAILED DESCRIPTION

Reference will now be made in more detail to aspects of some embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term ‘and/or’ includes any and all combinations of one or more of the associated listed items. Throughout the disclosure, the expression “at least one of a, b or c” indicates only a, only b, only c, both a and b, both a and c, both b and c, all of a, b, and c, or variations thereof.

The disclosure may be subject to various modifications and may have various embodiments, and specific embodiments are illustrated in the drawings and described in more detail in the description. The effects and features of the disclosure, and methods for achieving the effects and features will become apparent by referring to embodiments described below in more detail along with the drawings. However, the disclosure is not limited to the embodiments disclosed hereinafter, but may be implemented in diverse forms.

Hereinafter, aspects of some embodiments will be described in more detail with reference to the accompanying drawings, and when explaining with reference to the drawings, identical or corresponding components are denoted by the same reference numerals and some repeated explanations thereof may be omitted.

In the following embodiments, when one component is described as being “on” another component, the one component may be directly on the other component or one or more intervening components may also be present between the one component and the other component. In addition, when one component is described as being “under” another component in the following embodiments, the one component may be directly under the other component or one or more intervening components may also be present between the one component and the other component.

Also, for the convenience of explanation, the components in the drawings may be exaggerated or reduced in size. For example, the size and thickness of each configuration shown in the drawings are arbitrarily shown for convenience of explanation, so the disclosure is not necessarily limited to what is illustrated. That is, for convenience of explanation, the size, thickness, and ratio of the components shown in the drawings may be exaggerated and/or simplified for clarity. Therefore, spatially relative terms such as “below,” “beneath,” “lower,” “above,” “upper,” etc., may be used herein for ease of description to describe the relationship of one element or feature to another element(s) or feature(s).

The terms used in this specification to describe space, direction, etc., are terms for describing the space and direction shown in the drawings, but may be understood as terms for describing various other directions or various perspectives. For example, when the device or component shown in the drawing is flipped over, the device or component described as “below” may be interpreted in another direction (e.g., rotated 90 degrees, in the opposite direction, etc.). For example, when the device or component shown in the drawing is flipped over, the device or component described as “on” may be interpreted in another direction (e.g., rotated 90 degrees, in the opposite direction, etc.). Therefore, “below” and “on” may include both up and down directions. Also, the device or component may be oriented differently from the drawing, and the description according to the space or direction described in this specification may be interpreted in various ways.

In the description of processing processes, manufacturing methods, etc. in this specification, the order of processes or methods understood may be different from the order described. For example, two processes or two methods described consecutively may be performed simultaneously or substantially simultaneously, or may be performed in the opposite order to that described.

In the following embodiments, the x-axis, y-axis, and z-axis are not limited to three axes in an orthogonal coordinate system, but may be interpreted in a broader sense including these three axes of the orthogonal coordinate system. For example, the x-axis, y-axis, and z-axis may be orthogonal to each other, or may refer to different directions that are not orthogonal to each other.

In this specification, terms such as “first,” “second,” “third,” etc. may be used to describe specific components of this specification, and these terms “first,” “second,” “third,” etc. may be used to distinguish one component from another component.

When one component is mentioned as being “connected to” or “coupled to” another component, the connection or coupling may be understood as direct or indirect between the one component and the other component.

Similarly, when one component is said to be “electrically connected” to another component, one component and the other component may be directly and electrically connected, or may be indirectly and electrically connected through a conductive component.

Also, when one component is mentioned to be “between” two components, the arrangement may be understood that the one component is the only component placed between the two components, or the arrangement may be understood that components other than the one component are placed between the two components.

The terms used in this specification are used to describe specific embodiments and are not intended to limit the disclosure. The singular forms “a” and “an” used in this specification are intended to include the plural forms as well, unless the context clearly indicates otherwise.

For example, expressions such as “mixing,” “mixture,” “mix,” “have,” etc. specify the presence of described features, integers, steps, operations, elements, and/or components, but do not exclude the presence or addition of one or more other features, integers, steps, operations, elements, components, and/or groups thereof.

For example, terms such as “substantially,” “about,” and similar terms are used as terms of approximation rather than degree, and may be terms for explaining inherent variations in measurement or calculation values that may be recognized by those skilled in the art. For example, the use of terms such as “may,” “can,” etc. may be used to mean “one or more embodiments disclosed in this specification.”

For example, in this specification, when one layer has “the same layer structure” as another layer, the phrase “the same layer structure” may mean that multiple layers included in one layer may be included in the same order in the other layer. For example, multiple layers included in one layer and multiple layers included in another layer may each include the same material and be formed in the same order.

The electronic or electrical devices and/or any other related devices or components (for example, some of various modules) according to embodiments described in this specification may be implemented using any suitable hardware, firmware (for example, application-specific integrated circuits), software, or a combination of hardware, firmware, and software. For example, various components of these devices may be formed on a single integrated circuit (IC) chip or on separate IC chips. Moreover, various components of these devices may be formed on a flexible printed circuit film, tape carrier package (TCP), printed circuit board (PCB), or on a single substrate. Furthermore, various components of these devices may be processes or threads, executed on one or more processors, and may interact with other system components to execute computer program instructions and perform various functions described in this specification in one or more computing devices.

Computer program instructions are stored in memory that may be implemented in a computing device using, for example, standard memory devices such as Random Access Memory (RAM). Computer program instructions may also be stored on other non-transitory computer-readable media such as, for example, Compact Disc Read Only Memory (CD-ROM), flash drives, etc. Also, those skilled in the art will appreciate that the functions of various computing devices may be combined or integrated into a single computing device, or the functions of a particular computing device may be distributed across one or more other computing devices without departing from the spirit and scope of the disclosed embodiments.

Hereinafter, based on the above contents, a display device according to some embodiments will be described in more detail as follows.

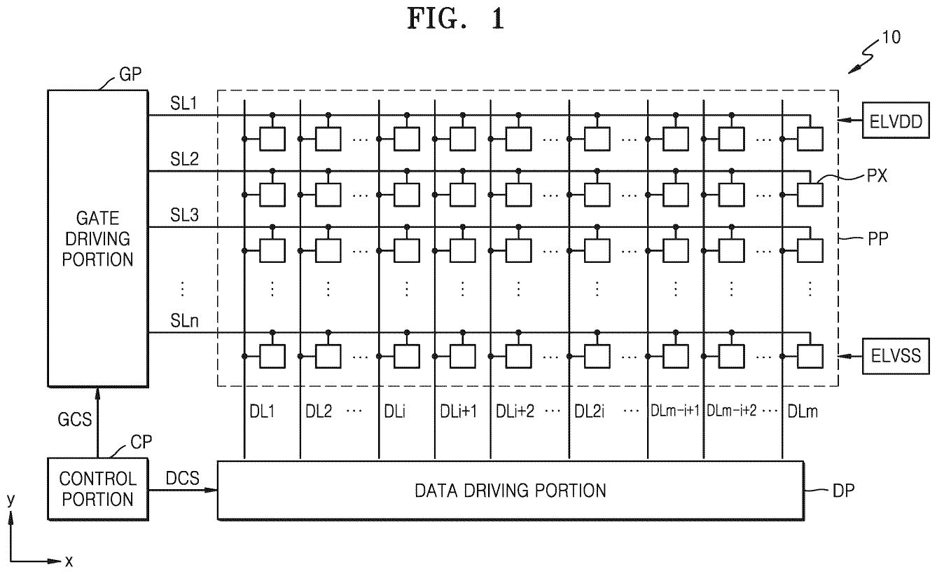

FIG. 1 is a conceptual diagram schematically illustrating aspects of a display panel according to some embodiments. The display panel may be included or incorporated within an electronic device configured to display images. The electronic device may include, for example, a television, a computer monitor, a smartphone, laptop computer, tablet computer, wearable electronic device (e.g., an augmented reality device, a virtual reality device, a smartwatch, etc.), a vehicle dash or display system, and the like, or any other electronic device configured to display images.

As shown in FIG. 1, the display panel may include a pixel portion PP, a gate driving portion (or referred to as a gate driver) GP, a data driving portion (or referred to as a data driver) DP, and a control portion (or referred to as a controller) CP.

The pixel portion PP in which a plurality of sub-pixels PX are arranged may be provided in a display area DA of the display panel. The gate driving portion GP, the data driving portion DP, and the control portion CP may be provided in a peripheral area PA of the display panel.

Each of the plurality of sub-pixels PX may be connected to a corresponding scan line among a plurality of scan lines SL1 to SLn (where n is an integer larger than 1) and a corresponding data line among a plurality of data lines DL1 to DLm (where m is an integer larger than 1). Further, in FIG. 1, scan lines SL2 and SL3, data lines DL2, DLi, DLi+1, DLi+2, DL2i, DLm−i+1, DLm−i+2, and the like are also briefly illustrated. The plurality of scan lines SL1 to SLn may each extend in a first direction (for example, an x direction or a row direction) to be respectively connected to the sub-pixels PX located in a same row. The plurality of scan lines SL1 to SLn may respectively deliver gate signals to the sub-pixels PX in the same row. The plurality of data lines DL1 to DLm may each extend in a second direction (for example, a y direction or a column direction) to be connected to the sub-pixels PX located in a same column.

The gate driving portion GP may be connected to the plurality of scan lines SL1 to SLn, generate gate signals in response to a gate driving control signal GCS from the control portion CP, and sequentially supply the gate signals to the plurality of scan lines SL1 to SLn. When the gate signals are sequentially supplied to the plurality of scan lines SL1 to SLn, the plurality of sub-pixels PX may be selected in units of rows. The plurality of data lines DL1 to DLm may each deliver data signal DATA to the sub-pixels PX in the selected row. Each of the plurality of scan lines SL1 to SLn may be connected to the gate of a transistor (or referred to as “thin-film transistor”) included in a sub-pixel PX. The gate signals may be gate control signals for controlling the transistors connected to the plurality of scan lines SL1 to SLn to turn on or off. The gate signals may be square wave signals in which an on voltage at which the transistors may be turned on and an off voltage at which the transistors may be turned off are repeated.

The data driving portion DP may convert image signals into data signals DATA in the form of voltage or current according to a data driving control signal DCS input from the control portion CP.

The control portion CP may generate a data driving control signal DCS and a gate driving control signal GCS in response to synchronization signals supplied from an external source. The control portion CP may output the data driving control signal DCS to the data driving portion DP and output the gate driving control signal GCS to the gate driving portion GP.

The gate driving portion GP and control portion CP may be directly formed on a substrate 100. The data driving portion DP may be located on a flexible printed circuit board (FPCB) electrically connected to a pad located on one side of the substrate 100. According to some embodiments, the data driving portion DP may be directly located on the substrate 100 in Chip On Glass (COG) or Chip On Plastic (COP) manner.

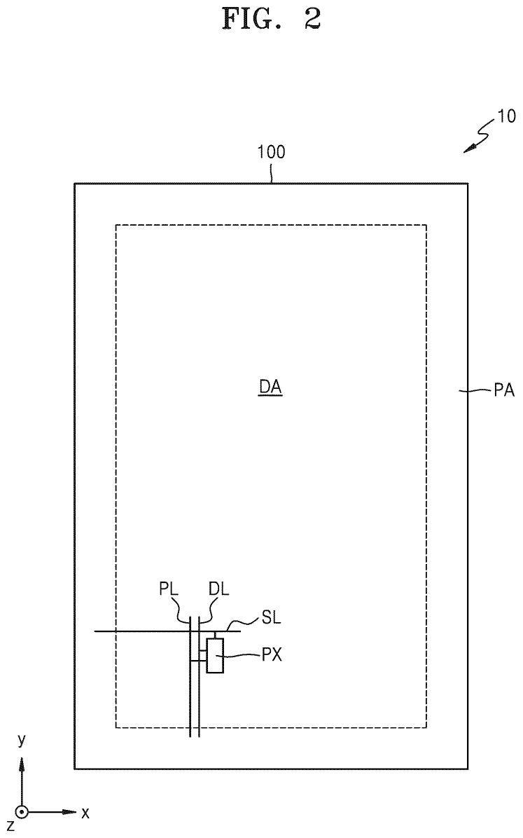

FIG. 2 is a plan view schematically illustrating further details of a display panel according to some embodiments.

As shown in FIG. 2, the display panel 10 includes the display area DA and the peripheral area PA located outside (e.g., in a periphery or outside a footprint of) the display area DA. In FIG. 2, the display area DA is shown to have a rectangular shape, but the disclosure is not limited thereto. The display area DA may have various shapes such as, a circular shape, an elliptical shape, a polygonal shape, or any suitable geometric shape.

The display area DA is a portion for displaying images, and the plurality of sub-pixels PX may be located therein. Each of the plurality of sub-pixels PX may include a display element such as an organic light-emitting device. Each of the plurality of sub-pixels PX may emit, for example, red, green, or blue light. The plurality of sub-pixels PX may be connected to a pixel circuit including thin-film transistors (TFTs), storage capacitors, etc. The pixel circuit may be connected to a scan line SL that transmits scan signals, a data line DL that intersects the scan line SL and transmits data signals, and a driving voltage line PL that supplies a driving voltage. For example, the data line DL and the driving voltage line PL may extend in the y direction (hereinafter, the first direction), and the scan line SL may extend in the x direction (hereinafter, the second direction).

Each of the plurality of sub-pixel PX may emit light with a luminance corresponding to an electrical signal from the electrically connected pixel circuit. The display area DA may display a preset image through light emitted from the plurality of sub-pixels PX. For reference, each of the plurality of sub-pixels PX may be defined as a light-emitting area that emits light of one color among red, green, and blue.

The peripheral area PA is an area where the plurality of sub-pixels PX are not located and may be an area that does not display images. Power supply wiring for driving the plurality of sub-pixels PX may be located in the peripheral area PA. Additionally, pads may be located in the peripheral area PA, and may be electrically connected to integrated circuit devices such as printed circuit boards including driving circuits or driver ICs in the peripheral area PA.

For reference, because the display panel 10 includes the substrate 100, the substrate 100 may be described as including the display area DA and the peripheral area PA. Details about the substrate 100 will be described later below.

Also, a plurality of transistors may be located in the display area DA. Depending on the type of the plurality of transistors (N-type or P-type) and/or operating conditions thereof, a first terminal of each of the plurality of transistors may be a source electrode or a drain electrode, and a second terminal may be an electrode different from the first terminal. For example, when the first terminal is the source electrode, the second terminal may be the drain electrode.

In the following descriptions, although an organic light-emitting display device is described as an example of a display device according to some embodiments, the display device of the disclosure is not limited thereto. According to some embodiments, the display device of the disclosure may be an inorganic light-emitting display device or a display device such as a quantum dot light-emitting display device. For example, the light-emitting layer of a display element included in the display device may include organic materials or inorganic materials. Also, the display device may include a light-emitting layer and quantum dots located in the path of light emitted from the light-emitting layer.

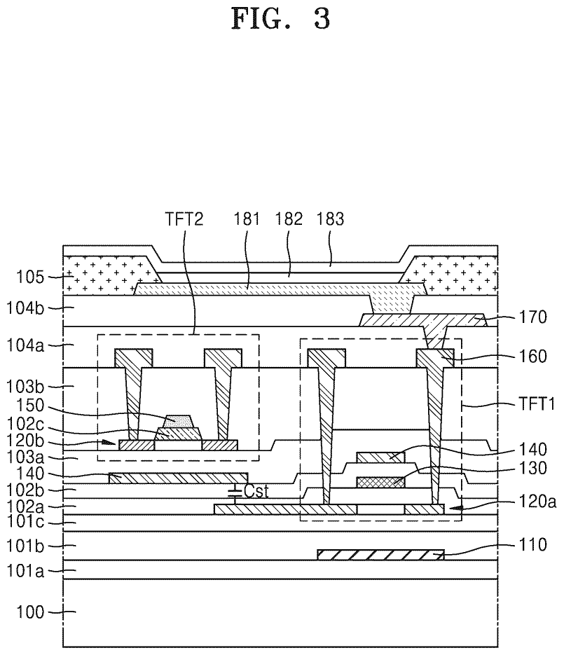

FIG. 3 is a cross-sectional view schematically illustrating a portion of the display device of FIG. 1.

The substrate 100 may include areas corresponding to the display area DA and the peripheral area PA outside the display area, as described earlier. The substrate 100 may include various materials with flexible or bendable characteristics. For example, the substrate 100 may include glass, a metal, or a polymer resin. Additionally, the substrate 100 may include polymer resins such as polyethersulphone, polyacrylate, polyetherimide, polyethylene naphthalate, polyethylene terephthalate, polyphenylene sulfide, polyarylate, polyimide, polycarbonate, or cellulose acetate propionate.

The substrate 100 may be variously modified, such as having a multilayer structure including two layers each containing such polymer resins and a barrier layer containing inorganic materials (such as silicon oxide, silicon nitride, silicon oxynitride, etc.) located between the layers.

A first barrier layer 101a may be located on the substrate 100. The first barrier layer 101a may include inorganic materials such as silicon oxide, silicon nitride, and/or silicon oxynitride, and may be located between the substrate 100 and a lower metal layer 110 (or a second barrier layer 101b). The first barrier layer 101a may have a shape corresponding to an entire surface of the substrate 100 and may be formed through Chemical Vapor Deposition (CVD) or Atomic Layer Deposition (ALD). The first barrier layer 101a may prevent or reduce the diffusion of impurity ions, prevent or reduce the penetration of moisture or external air, and planarize the surface of the substrate 100.

The lower metal layer 110 may be located on the first barrier layer 101a. The lower metal layer 110 may be located below a first semiconductor layer 120a and may include at least one metal among molybdenum (Mo), aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), titanium (Ti), tungsten (W), and copper (Cu). For example, in a plan view of the pixel circuit, at least a portion of the lower metal layer 110 may overlap at least a portion of the first semiconductor layer 120a. For example, in a plan view of the pixel circuit, at least a portion of the lower metal layer 110 may overlap at least a portion of a first gate layer 130.

The second barrier layer 101b may be located on the lower metal layer 110. The second barrier layer 101b may include inorganic materials such as silicon oxide, silicon nitride, and/or silicon oxynitride, and may be located between the first barrier layer 101a and a buffer layer 101c. The second barrier layer 101b may have a shape corresponding to the entire surface of the substrate 100 and may be formed through CVD or ALD. The second barrier layer 101b may prevent or reduce the diffusion of impurity ions, prevent or reduce the penetration of moisture or external air, and planarize the surface of the substrate 100 or the first barrier later 101a.

The buffer layer 101c may be located on the second barrier layer 101b. The buffer layer 101c may include inorganic materials such as silicon oxide, silicon nitride, and/or silicon oxynitride, and may be located between the second barrier layer 101b and the first semiconductor layer 120a. The buffer layer 101c may planarize the surface of the substrate 100 of the second barrier layer 101b, and during a crystallization process for forming the first semiconductor layer 120a, the buffer layer 101c may control a rate of heat supply to allow the first semiconductor layer 120a to crystallize uniformly.

The first semiconductor layer 120a may be located on the buffer layer 101c. The first semiconductor layer 120a may include polysilicon (for example, low-temperature polycrystalline silicon), and may include a channel region not doped with impurities and source-drain regions formed by being doped with the impurities on both sides of the channel region. The impurities may vary depending on a type of thin-film transistor, and may be N-type impurities or P-type impurities.

A first gate insulating layer 102a may be located on the first semiconductor layer 120a. The first gate insulating layer 102a may be a configuration to ensure insulation between the first semiconductor layer 120a and the first gate layer 130. The first gate insulating layer 102a may include inorganic materials such as silicon oxide, silicon nitride, and/or silicon oxynitride, and may be located between the first semiconductor layer 120a and the first gate layer 130. The first gate insulating layer 102a may have a shape corresponding to the entire surface of the substrate 100 and may have a structure with contact holes formed in preset portions. The first gate insulating layer 102a may be formed through CVD or ALD.

The first gate layer 130 may be located on the first gate insulating layer 102a. The first gate layer 130 may be positioned or arranged to overlap vertically the first semiconductor layer 120a, and may include at least one metal among molybdenum (Mo), aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), titanium (Ti), tungsten (W), and copper (Cu).

A second gate insulating layer 102b may be located on the first gate layer 130. The second gate insulating layer 102b may ensure insulation between the first gate layer 130 and a second gate layer 140. The second gate insulating layer 102b may include inorganic materials such as silicon oxide, silicon nitride, and/or silicon oxynitride, and may be located between the first gate layer 130 and the second gate layer 140. The second gate insulating layer 102b may have a shape corresponding to the entire surface of the substrate 100 and may have a structure with contact holes formed in preset portions. The second gate insulating layer 102b may be formed through CVD or ALD.

The second gate layer 140 may be located on the first gate insulating layer 102a. The second gate layer 140 may be positioned to overlap the first gate layer 130 and/or a second semiconductor layer 120b in a plan view of the pixel circuit, and may include at least one metal among molybdenum (Mo), aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), titanium (Ti), tungsten (W), and copper (Cu). According to some embodiments, the display panel 10 may further include another gate layer located on a different layer.

A first interlayer insulating film 103a may be located on the second gate layer 140. The first interlayer insulating film 103a may cover the second gate layer 140. The first interlayer insulating film 103a may include inorganic material. For example, the first interlayer insulating film 103a may include a metal oxide or metal nitride, and specifically, the inorganic material may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂). For example, the first interlayer insulating film 103a may have a double structure of SiOx/SiNy or SiNx/SiOy.

The second semiconductor layer 120b may be located on the first interlayer insulating film 103a. The second semiconductor layer 120b may include polysilicon (for example, low-temperature polycrystalline silicon) or may be an oxide semiconductor layer (for example, Indium Gallium Zinc Oxide (IGZO), Indium Zinc Oxide (IZO), etc.). The second semiconductor layer 120b may include a channel region not doped with impurities and source-drain regions formed by being doped with impurities on both sides of the channel region. For example, when the second semiconductor layer 120b includes polysilicon, the impurities may vary depending on a type of thin-film transistor and may be N-type impurities or P-type impurities. For example, when the second semiconductor layer 120b is an oxide semiconductor layer, the oxide semiconductor layer may generally be a P-type semiconductor layer.

A third gate insulating layer 102c may be located on the second semiconductor layer 120b. The third gate insulating layer 102c may ensure insulation between the second semiconductor layer 120b and a third gate layer 150. The third gate insulating layer 102c may include inorganic materials such as silicon oxide, silicon nitride, and/or silicon oxynitride, and may be located between the second semiconductor layer 120b and the third gate layer 150. The third gate insulating layer 102c may have a shape corresponding to the entire surface of the substrate 100 and may have a structure with contact holes formed in preset portions. The third gate insulating layer 102c may be formed through CVD or ALD.

The third gate layer 150 may be located on the third gate insulating layer 102c. The third gate layer 150 may be positioned to vertically overlap the second semiconductor layer 120b, and may include at least one metal among molybdenum (Mo), aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), titanium (Ti), tungsten (W), and copper (Cu).

A second interlayer insulating film 103b may be located on the third gate layer 150. The second interlayer insulating film 103b may cover the third gate layer 150 and/or the first interlayer insulating film 103a. The second interlayer insulating film 103b may include inorganic material. For example, the second interlayer insulating film 103b may be a metal oxide or metal nitride, and specifically, the inorganic material may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂). For example, the second interlayer insulating film 103b may have a double structure of SiOₓ/SiN_{y} or SiNₓ/SiO_{y}.

A first conductive layer 160 may be located on the second interlayer insulating film 103b. The first conductive layer 160 may serve as an electrode connected to the source/drain regions of the second semiconductor layer 120b and/or the first semiconductor layer 120a through a through-hole included in the second interlayer insulating film 103b and/or a through-hole included in the first interlayer insulating film 103a, the second interlayer insulating film 103b, the first gate insulating layer 102a, and the second gate insulating layer 102b.

The first conductive layer 160 may include one or more metals selected from aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). For example, the first conductive layer 160 may include a Ti layer, an Al layer, and/or a Cu layer. For example, the first conductive layer 160 may include a Ti/Al/Ti structure.

For example, the first conductive layer may directly contact a source region or a drain region of a semiconductor layer (for example, the first semiconductor layer 120a or the second semiconductor layer 120b) through a through-hole formed in an insulating layer located below. In this case, an area of the first conductive layer 160 which directly contacts the source region may be the source electrode, and the area of the first conductive layer 160 which directly contacts the drain region may be the drain electrode. The source-drain electrode used in this specification may refer to a portion of the first conductive layer 160 which directly contacts the source region or drain region of the semiconductor layer. The source region and the drain region in the semiconductor layer may be determined depending on whether the semiconductor layer is n-type or p-type.

A first organic insulating layer 104a may be located on the first conductive layer 160. The first organic insulating layer 104a may be an organic insulating layer that covers the top of the first conductive layer 160 and has a generally flat upper surface so as to serve as a planarization film. The first organic insulating layer 104a may include organic materials such as acrylic, Benzocyclobutene (BCB) or hexamethyldisiloxane (HMDSO). The first organic insulating layer 104a may have various modifications in which the first organic insulating layer 104a includes a single layer or multiple layers.

A second conductive layer 170 may be located on the first organic insulating layer 104a. The second conductive layer 170 may be connected to the portion of the first conductive layer that is connected to the first semiconductor layer 120a through a through-hole included in the first organic insulating layer 104a, thereby serving as an electrode.

The second conductive layer 170 may include one or more metals from among aluminum (Al), platinum (Pt), palladium (Pd), silver (Ag), magnesium (Mg), gold (Au), nickel (Ni), neodymium (Nd), iridium (Ir), chromium (Cr), lithium (U), calcium (Ca), molybdenum (Mo), titanium (Ti), tungsten (W), and copper (Cu). For example, the second conductive layer 170 may include a Ti layer, an Al layer, and/or a Cu layer. For example, the second conductive layer 170 may include a Ti/Al/Ti structure.

According to some embodiments, the display panel 10 may further include another conductive layer located on a different layer, and the other conductive layer may, for example, be a wiring layer that serves as wiring.

A second organic insulating layer 104b may be located on the second conductive layer 170. The second organic insulating layer 104b may be an organic insulating layer that covers the top of the second conductive layer 170 and has a generally flat upper surface so as to serve as a planarization film. The second organic insulating layer 104b may include organic materials such as acrylic, BCB or HMDSO. The second organic insulating layer 104b may have various modifications in which the second organic insulating layer 104b has a single layer or multiple layers.

A pixel electrode layer 181 may be located on the second organic insulating layer 104b. The pixel electrode layer 181 may be connected to the second conductive layer 170 through a contact hole formed in the second organic insulating layer 104b. A display element may be located on the pixel electrode layer 181. For example, a light-emitting element such as an organic light-emitting device may be used as the display element. For example, the organic light-emitting device may be included in an intermediate layer 182, and the intermediate layer 182 may be located on pixel electrodes implemented for each sub-pixel through the pixel electrode layer 181. For example, the pixel electrode layer 181 may include a transparent conductive layer including a transparent conductive oxide such as Indium Tin Oxide (ITO), In₂O₃ or IZO, and/or a reflective layer including a metal such as Al or Ag. For example, the pixel electrode layer 181 may have a 3-layer structure of ITO/Ag/ITO.

A pixel defining layer 105 may be located on top of the second organic insulating layer 104b and may be arranged to cover edges of the pixel electrodes implemented for each sub-pixel through the pixel electrode layer 181. For example, the pixel defining layer 105 may cover the edges of the pixel electrodes implemented for each sub-pixel. The pixel defining layer 105 may have an opening corresponding to each sub-pixel, and the opening may be formed so that at least the central portion of the pixel electrode implemented for each sub-pixel is exposed. The opening may be defined by the pixel defining layer 105.

For example, the pixel defining layer 105 may include organic materials such as polyimide or HMDSO (hexamethyldisiloxane). A spacer may be located in the pixel defining layer 105. The spacer is illustrated as being located in the peripheral area PA, but the spacer may be located on the display area DA. The spacer may prevent or reduce damage to the organic light-emitting device due to sagging of a mask in a manufacturing process using the mask. The spacer includes organic insulating material and may be formed as a single layer or multiple layers.

The intermediate layer 182 and a counter electrode 183 may be located in the aforementioned opening. The intermediate layer 182 includes low molecular or high molecular materials, and when the intermediate layer 182 includes the low molecular materials, the intermediate layer 182 may include a hole injection layer, a hole transport layer, an emission layer, an electron transport layer, and/or an electron injection layer. When the intermediate layer 182 includes the high molecular materials, the intermediate layer 182 may generally have a structure including the hole transport layer and the emission layer.

The structure of the intermediate layer 182 is not limited to the above description and may have other various structures. For example, at least one of the layers constituting the intermediate layer 182 may be integrally formed with the counter electrode 183. According to some embodiments, the intermediate layer 182 may have a layer patterned corresponding to each of the multiple pixel electrodes.

The counter electrode 183 may include a transparent conductive layer including a transparent conductive oxide such as ITO, In₂O₃ or IZO. The pixel electrode layer 181 may be used as an anode, and the counter electrode 183 may be used as a cathode. Polarities of the electrodes may be reversed.

The counter electrode 183 may be located on the top of the display area DA and may be arranged or formed on the entire surface of the display area DA. The counter electrode 183 may be integrally formed to cover multiple pixels. The counter electrode 183 may electrically contact a common power supply line located in the peripheral area PA. For example, the counter electrode 183 may extend to a partition wall.

A first thin-film transistor TFT1 may be a thin-film transistor including the aforementioned first semiconductor layer 120a. The first thin-film transistor TFT1 may be a PMOS type or an NMOS type, depending on a type of the first semiconductor layer 120a.

For example, a portion of the second gate layer 140 may be located below a portion of the second semiconductor layer 120b, and the portion of the second semiconductor layer 120b may be the lower gate electrode of a second thin-film transistor TFT2. The first semiconductor layer 120a of the first thin-film transistor TFT1 may extend toward the second thin-film transistor TFT2. As a result, a portion of the lower gate electrode and the portion of the first semiconductor layer 120a of the first thin-film transistor TFT1 may overlap in a plan view of the pixel circuit.

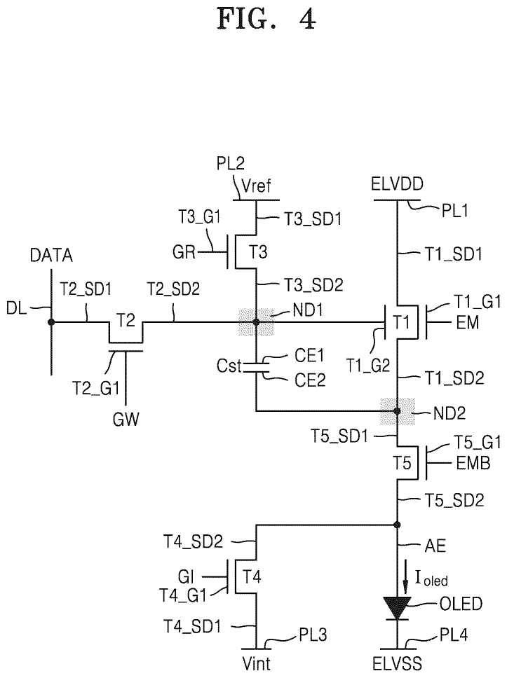

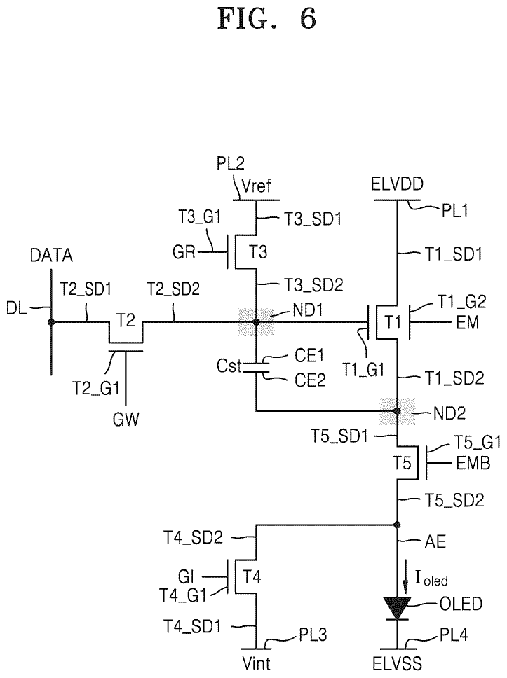

For example, a first electrode (see CE1 in FIGS. 4 and 6) of a storage capacitor Cst may be a portion of the lower gate electrode of the first thin-film transistor TFT1, and a second electrode (see CE2 in FIGS. 4 and 6) of the storage capacitor Cst may be a portion of the first semiconductor layer 120a of the second thin-film transistor TFT2.

FIG. 4 is an example of an equivalent circuit diagram schematically illustrating aspects of an example pixel circuit of a pixel of the display panel of FIG. 1. Although FIG. 4 illustrates various components in an example pixel circuit according to some embodiments, embodiments according to the present disclosure are not limited thereto, and according to some embodiments, the pixel circuit may include additional components or fewer components without departing from the spirit and scope of embodiments according to the present disclosure.

As shown in FIG. 4, the pixel circuit may include multiple switching elements. For example, the pixel circuit may have a 5T1C structure. For example, the multiple switching elements may include a first switching element T1 to a fifth switching element T5, and the pixel circuit may further include a light-emitting pixel and the storage capacitor Cst.

The first switching element T1 may be a driving thin-film transistor that controls the driving current I_{oled} flowing through the light-emitting element OLED. The first switching element T1 may be a thin-film transistor with a dual-gate structure.

For example, the first switching element T1 may include two source-drain electrodes and two gate electrodes. For example, the first switching element T1 may include a first-a source-drain electrode T1_SD1, a first-b source-drain electrode T1_SD2, a first-a gate electrode T1_G1, and a first-b gate electrode T1_G2.

A magnitude of the driving current I_{oled} delivered to the light-emitting element OLED may correspond to a data signal DATA transmitted through the first-b gate electrode T1_G2, which is the lower gate electrode of the first switching element T1. For example, the data signal DATA may include grayscale information, which is a degree of light emission of the light-emitting element OLED, and the magnitude of the driving current I_{oled} may vary according to the grayscale information. When the magnitude of the driving current I_{oled} changes, an intensity of light generated in the light-emitting element OLED may also change.

For example, in a cross-sectional view of the pixel circuit, the semiconductor layer (for example, the second semiconductor layer 120b in FIG. 3) may be located between the first-a gate electrode T1_G1 and the first-b gate electrode T1_G2, and the semiconductor layer may include source and drain regions corresponding to the two source-drain electrodes.

For example, the first-a gate electrode T1_G1 may be an upper gate electrode located on the semiconductor layer, and the first-b gate electrode T1_G2 may be the lower gate electrode located below the semiconductor layer. For example, the first switching element T1 may be turned on or off based on an emission control signal EM transmitted through the first-a gate electrode T1_G1, which is the upper gate electrode.

For example, the first switching element T1 may be the second thin-film transistor TFT2 in FIG. 3. The first switching element T1 may include the second semiconductor layer 120b containing an oxide semiconductor.

In a case of a driving thin-film transistor, as the driving time passes, holes may be trapped inside the driving thin-film transistor. When holes are trapped inside the driving thin-film transistor, the threshold voltage of the driving thin-film transistor may be changed by the trapped holes. When an oxide semiconductor is used as the semiconductor layer, an effect of preventing or reducing this hole trapping phenomenon is produced.

A second switching element T2 may be a switching thin-film transistor or a data control thin-film transistor. The second switching element T2 may be electrically connected to the data line DL that transmits the data signal DATA, and may or may not transmit the data signal DATA to the first switching element T1 through an on or off operation. The on or off operation of the second switching element T2 may be performed based on a data control signal GW. The second switching element T2 may control the transmission of the data signal DATA to the first switching element T1.

For example, the second switching element T2 may electrically connect between the data line DL and the first-b gate electrode T1_G2 of the first switching element T1. For example, the second switching element T2 may include a second-a source-drain electrode T2_SD1, a second-b source-drain electrode T2_SD2, and a second-a gate electrode T2_G1.

For example, the second-a source-drain electrode T2_SD1 may be electrically connected to the data line DL that transmits the data signal DATA, and the second-b source-drain electrode T2_SD2 may be electrically connected to the first-b gate electrode T1_G2, which is the lower gate electrode of the first switching element T1.

For example, the data control signal GW may be applied to the second-a gate electrode T2_G1. The second switching element T2 may be turned on or off according to the data control signal GW. The second switching element T2 may transmit the data signal DATA to the first-b gate electrode T1_G2 based on the data control signal GW.

For example, the second switching element T2 may include a second semiconductor layer 120b containing an oxide semiconductor.

The storage capacitor Cst may be electrically connected between the first-b gate electrode T1_G2, which is the lower gate electrode of the first switching element T1, and one of the source-drain electrodes of the first switching element T1. Depending on the connection position of the storage capacitor Cst, the first switching element T1 may be defined as a source follower.

For example, the storage capacitor Cst may include the first electrode CE1 electrically connected to the first-b gate electrode T1_G2, and the second electrode CE2 electrically connected to one of the source-drain electrodes of the first switching element T1. For example, when the first switching element T1 is an NMOS type, the second electrode CE2 may be electrically connected to the first-b source-drain electrode T1_SD2.

For example, the first electrode CE1 may be electrically connected to the second switching element T2. The first electrode CE1 may be electrically connected to the second-b source-drain electrode T2_SD2 of the second switching element T2.

For example, the first electrode CE1 may be electrically connected to a first node ND1. For example, the first node ND1 may be electrically connected to the first-b gate electrode T1_G2, the second-b source-drain electrode T2_SD2, the first electrode CE1, and the third-b source-drain electrode T3_SD2 to be described below. In this specification, being electrically connected to the first node ND1 may mean being electrically connected to other components connected to the first node ND1.

For example, the second electrode CE2 may be electrically connected to a second node ND2. For example, the second node ND2 may be electrically connected to the first-b source-drain electrode T1_SD2, the fifth-a source-drain electrode T5_SD1, and the second electrode CE2. In this specification, being electrically connected to the second node ND2 may mean being electrically connected to other components connected to the second node ND2.

A third switching element T3 may be a compensation thin-film transistor electrically connected between a reference voltage line PL2 that transmits a reference voltage Vref and the first node ND1. For example, the third switching element T3 may include a third-a source-drain electrode T3_SD1, a third-b source-drain electrode T3_SD2, and a third-a gate electrode T3_G1. For example, a compensation control signal GR may be transmitted through the third-a gate electrode T3_G1, and based on the compensation control signal GR, the third switching element T3 may be turned on or off. For example, the third-a source-drain electrode T3_SD1 may be electrically connected to the reference voltage line PL2, and the third-b source-drain electrode T3_SD2 may be electrically connected to the first node ND1.

For example, the third switching element T3 may include a second semiconductor layer 120b containing an oxide semiconductor.

A fourth switching element T4 may be an initialization thin-film transistor electrically connected between an initialization voltage line PL3 that transmits an initialization voltage Vint and an anode electrode AE of the light-emitting element OLED. For example, the fourth switching element T4 may include a fourth-a source-drain electrode T4_SD1, a fourth-b source-drain electrode T4_SD2, and a fourth-a gate electrode T4_G1. For example, an initialization control signal GI may be transmitted through the fourth-a gate electrode T4_G1, and based on the initialization control signal GI, the fourth switching element T4 may be turned on or off. For example, the fourth-a source-drain electrode T4_SD1 may be electrically connected to the initialization voltage line PL3, and the fourth-b source-drain electrode T4_SD2 may be electrically connected to the anode electrode AE of the light-emitting element OLED.

For example, the fourth switching element T4 may include the first semiconductor layer 120a containing low-temperature polysilicon.

A fifth switching element T5 may be an emission control thin-film transistor electrically connected between the second node ND2 and the anode electrode AE of the light-emitting element OLED. For example, the fifth switching element T5 may include a fifth-a source-drain electrode T5_SD1, a fifth-b source-drain electrode T5_SD2, and a fifth-a gate electrode T5_G1. For example, a second emission control signal EMB may be transmitted through the fifth-a gate electrode T5_G1, and based on the second emission control signal EMB, the fifth switching element T5 may be turned on or off. For example, the fifth-a source-drain electrode T5_SD1 may be electrically connected to the second node ND2, and the fifth-b source-drain electrode T5_SD2 may be electrically connected to the anode electrode AE of the light-emitting element OLED.

For example, the fifth switching element T5 may be the first thin-film transistor TFT1 in FIG. 3. The fifth switching element T5 may include a portion of the first semiconductor layer 120a containing low-temperature polysilicon.

Referring to FIGS. 3 and 4, the first switching element T1 may be the second thin-film transistor TFT2 in FIG. 3, and the fifth switching element T5 may be the first thin-film transistor TFT1 in FIG. 3. For example, the first electrode CE1 of the storage capacitor Cst in FIG. 4 may be a portion of the first-b gate electrode T1_G2, which is the lower gate electrode of the first switching element T1, and the second electrode CE2 of the storage capacitor Cst in FIG. 4 may be a portion of the first semiconductor layer 120a. For example, the second electrode CE2 of the storage capacitor Cst in FIG. 4 may be a portion of the source-drain region of the first semiconductor layer 120a.

For example, a portion of the first-b gate electrode T1_G2, which is the lower gate electrode of the first switching element T1, and a portion of the first semiconductor layer 120a of the fifth switching element T5 may overlap in a plan view of the pixel circuit.

For example, the portion of the first semiconductor layer 120a of the fifth switching element T5, which is the second electrode CE2, may be electrically connected to one of the source-drain electrodes of the fifth switching element T5 (for example, the fifth-a source-drain electrode T5_SD1). For example, the portion of the first semiconductor layer 120a of the fifth switching element T5, which is the second electrode CE2, may be electrically connected to one of the source-drain electrodes of the first switching element T1 (through the fifth-a source-drain electrode T5_SD1).

The light-emitting element OLED may include an anode electrode AE electrically connected to the fourth switching element T4 and the fifth switching element T5. The light-emitting element OLED may be electrically connected to a second power voltage line PL4 that transmits a second power voltage ELVSS.

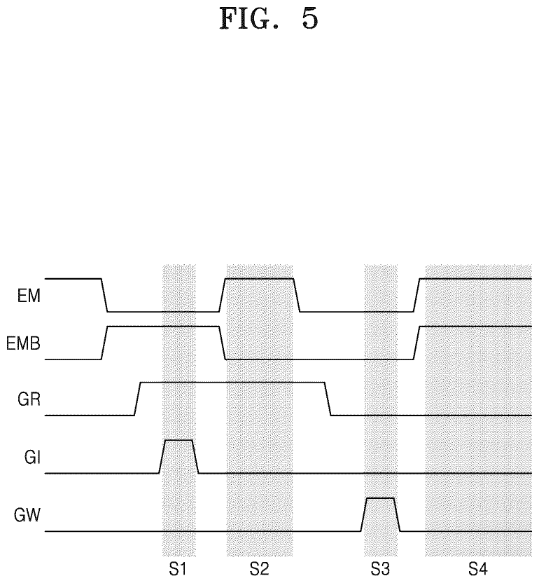

FIG. 5 is a timing diagram illustrating control signals transmitted to each switching element of the pixel circuit in FIG. 4.

As shown in FIGS. 4 and 5, the emission control signal EM, the second emission control signal EMB, the compensation control signal GR, the initialization control signal GI, and the data control signal GW may be applied to the pixel circuit. The steps of pixel circuit operation may be explained according to the steps in which the control signals are applied. For example, when the control signals in FIG. 5 rise, the control signals may be on signals, and when the control signals fall, the control signals may be off signals. Hereinafter, control signals other than those mentioned for each step may be off signals.
First step: Compensation control signal GR, second emission control signal EMB, and initialization control signal GI on (S1 interval in FIG. 5)

A first step may be a step where the compensation control signal GR, the second emission control signal EMB, and the initialization control signal GI rise. The first step may be a storage capacitor Cst initialization step. When the risen compensation control signal GR is applied to the third switching element T3, the third switching element T3 may be turned on. When the third switching element T3 is turned on, the reference voltage Vref may be applied to the first electrode CE1 of the storage capacitor Cst. When the risen initialization control signal GI is applied to the fourth switching element T4 and the risen second emission control signal EMB is applied to the fifth switching element T5, the fourth switching element T4 and the fifth switching element T5 may be turned on. Holes trapped in the second electrode CE2 may be discharged through the turned-on fourth switching element T4 and fifth switching element T5. In order to enable a discharge of trapped holes from the second electrode CE2, the reference voltage Vref (for example, positive or about 2.5V) may be greater than the initialization voltage Vint (for example, negative or about −2.5V).
Second step: Compensation control signal GR and emission control signal EM on (S2 interval in FIG. 5)

The second step may be a step where the second emission control signal EMB falls again, the initialization control signal GI falls again, the compensation control signal GR is still in a risen state, and the emission control signal EM rises. The second step may be a threshold voltage compensation step for the first switching element T1.

When the risen emission control signal EM is applied to the first switching element T1, the first switching element T1 may be turned on. When the first switching element T1 is turned on, a difference between the reference voltage Vref and the threshold voltage may be applied to the second electrode CE2. The threshold voltage of the first switching element T1 may be initialized by the reference voltage Vref applied through the third switching element T3.
Third step: Data control signal GW on (S3 interval in FIG. 5)

The third step may be a step where the compensation control signal GR and the emission control signal EM fall, and the data control signal GW rises. The third step may be a data signal DATA writing step. When the risen data control signal GW is applied to the second switching element T2, the second switching element T2 may be turned on. The data signal DATA may be written to the storage capacitor Cst through the second switching element T2.
Fourth step: Emission control signal EM and second emission control signal EMB on (S4 interval in FIG. 5)

The fourth step may be a step where the data control signal GW falls again, and the emission control signal EM and the second emission control signal EMB rise. The fourth step may be an emission step.

When the risen emission control signal EM is applied to the first switching element T1 and the risen second emission control signal EMB is applied to the fifth switching element T5, the first switching element T1 and the fifth switching element T5 may be turned on. When the first switching element T1 and the fifth switching element T5 are turned on, the driving current I_{oled} may be delivered to the light-emitting element OLED. The light-emitting element OLED may emit light in response to the driving current I_{oled}.

FIG. 6 is another example of the equivalent circuit diagram schematically illustrating the pixel circuit of the display panel of FIG. 1. For reference, in the description of FIG. 6, some content that is identical to or overlaps with the previously described content may be omitted. Although FIG. 6 illustrates various components in an example pixel circuit according to some embodiments, embodiments according to the present disclosure are not limited thereto, and according to some embodiments, the pixel circuit may include additional components or fewer components without departing from the spirit and scope of embodiments according to the present disclosure.

As shown in FIG. 6, the first-a gate electrode T1_G1, which is the upper gate electrode of the first switching element T1, may be electrically connected to the first node ND1. The first node ND1 may be electrically connected to the second switching element T2, the third switching element T3, and the storage capacitor Cst. For example, the first node ND1 may be electrically connected to the second-b source-drain electrode T2_SD2 of the second switching element T2, the third-b source-drain electrode T3_SD2 of the third switching element T3, the first-a gate electrode T1_G1 of the first switching element T1, and the first electrode CE1 of the storage capacitor Cst.

The emission control signal EM may be applied to the first-b gate electrode T1_G2, which is the lower gate electrode of the first switching element T1. The second node ND2 may be electrically connected to the storage capacitor Cst and the fifth switching element T5. For example, the second node ND2 may be electrically connected to the first-b source-drain electrode T1_SD2 of the first switching element T1, the second electrode CE2 of the storage capacitor Cst, and the fifth-a source-drain electrode T5_SD1 of the fifth switching element T5.

The gate electrodes of the first switching element T1 in FIG. 6 may have a different connection structure from the gate electrodes of the first switching element T1 in FIG. 4. The data signal DATA may be applied to the first-a gate electrode T1_G1, and the emission control signal EM may be applied to the first-b gate electrode T1_G2. Based on the data signal DATA and the emission control signal EM, the first switching element T1 may be turned on, and the driving current I_{oled} may be controlled. When the second emission control signal EMB is applied to the fifth-a gate electrode T5_G1 of the fifth switching element T5, the fifth switching element T5 may be turned on, and the driving current I_{oled} may be delivered to the light-emitting element OLED through the fifth switching element T5.

The first electrode CE1 of the storage capacitor Cst in FIG. 6 may be a portion of the third gate layer 150 included in the second thin-film transistor TFT2 in FIG. 3. The second electrode CE2 of the storage capacitor Cst may be a portion of the first semiconductor layer 120a included in the first thin-film transistor TFT1 in FIG. 3.

The portion of the third gate layer 150 included in the second thin-film transistor TFT2 in FIG. 3 and the portion of the first semiconductor layer 120a included in the first thin-film transistor TFT1 in FIG. 3 may overlap in a plan view of the pixel circuit.

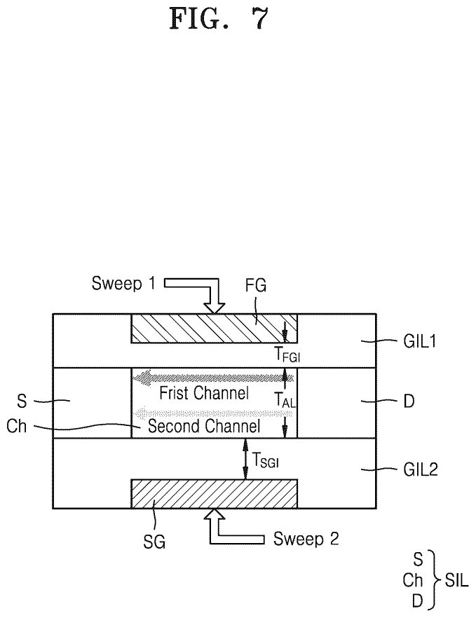

FIG. 7 is a cross-sectional view schematically illustrating an example of a thin-film transistor having a dual-gate structure.

As shown in FIG. 7, the thin-film transistor with a dual-gate structure may include an upper gate electrode FG and a lower gate electrode SG. The thin-film transistor with the dual-gate structure may include a source region S, a channel region Ch, and a drain region D of a semiconductor layer SIL located between an upper gate electrode FG and a lower gate electrode SG.

When a control signal is applied to the upper gate electrode FG (Sweep 1 step), a first channel may be formed between the source region S and the drain region D. When a control signal is applied to the lower gate electrode SG (Sweep 2 step), a second channel may be formed between the source region S and the drain region D.

A first distance T_{FGI} between the upper gate electrode FG and the semiconductor layer SIL may be smaller than a second distance T_{SGI} between the lower gate electrode SG and the semiconductor layer SIL. As a result, a number of holes (or charges) transmitted through the first channel may be greater than a number of holes (or charges) transmitted through the second channel. Due to a difference in distances (T_{FGI}−T_{SGI}), the current transmitted through the source-drain region may be more influenced by the upper gate electrode FG. A thickness T_{AL} of the semiconductor layer SIL may be greater than the first distance T_{FGI} and greater than the second distance T_{SGI}.

A first insulating layer GIL1 may be located between the upper gate electrode FG and the semiconductor layer SIL. A second insulating layer GIL2 may be located between the lower gate electrode SG and the semiconductor layer SIL.

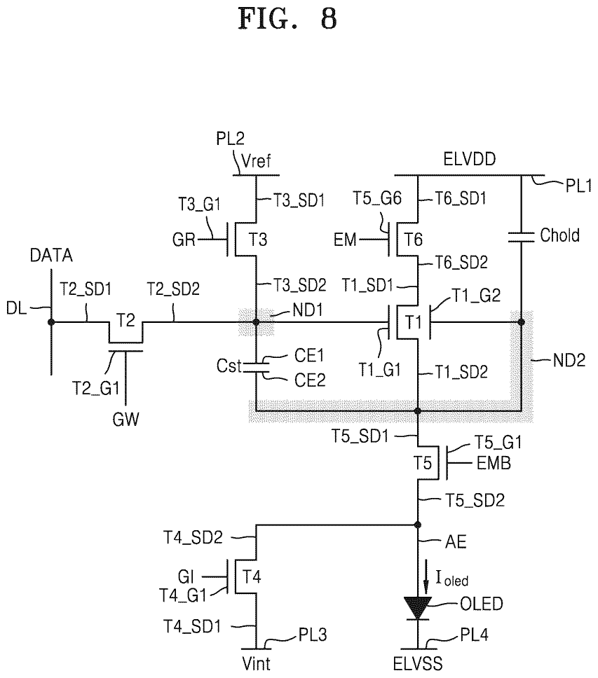

FIG. 8 is an example of an equivalent circuit diagram schematically illustrating a pixel circuit of a display panel according to a comparative example. For reference, in the description of FIG. 8, content that is identical to or overlaps the previously described content may be omitted.

As shown in FIG. 8, the pixel circuit in FIG. 8 may further include a sixth switching element T6, in addition to the fifth switching element T5. The component that is turned on or off according to the emission control signal EM may be the sixth switching element T6 other than the first switching element T1.

The first-a source-drain electrode T1_SD1 of the first switching element T1 may be electrically connected to a sixth-b source-drain electrode T6_SD2 of the sixth switching element T6. The sixth-a source-drain electrode T6_SD1 of the sixth switching element T6 may be electrically connected to the power voltage line PL1 that delivers the power voltage ELVDD.

The first-a gate electrode T1_G1 of the first switching element T1 may be electrically connected to the second switching element T2, the third switching element T3, and the first electrode CE1 of the storage capacitor Cst. The first-b gate electrode T1_G2 of the first switching element T1 may be electrically connected to the second electrode CE2 of the storage capacitor Cst and the fifth switching element T5. The first-b gate electrode T1_G2 of the first switching element T1 may be electrically connected to the hold capacitor Chold.

One electrode of the hold capacitor Chold may be electrically connected to the power voltage line PL1, and the other electrode of the hold capacitor Chold may be electrically connected to the first-b gate electrode T1_G2, the second electrode CE2 of the storage capacitor Cst, and the fifth-a source-drain electrode T5_SD1 of the fifth switching element T5.

The pixel circuit in FIG. 8 includes one more switching element and one more capacitor, compared to the pixel circuits in FIGS. 4 and 6. Therefore, the pixel circuit in FIG. 8 has the problem of occupying more area than the pixel circuits in FIGS. 4 and 6.

In particular, the pixel circuit according to the comparative example includes two emission control transistors (the fifth switching element T5 and the sixth switching element T6). In contrast, because the pixel circuits in FIGS. 4 and 6 apply the emission control signal EM to the driving thin-film transistor, the sixth switching element T6 may be omitted in the pixel circuits of FIGS. 4 and 6.

Thus, the pixel circuits in FIGS. 4 and 6 may be pixel circuits in which one thin-film transistor and one capacitor are omitted from the pixel circuit in FIG. 8. Even some components are omitted, the pixel circuits in FIGS. 4 and 6 may perform the same operation as the pixel circuit in FIG. 8. Therefore, the pixel circuits in FIGS. 4 and 6 may occupy an area that is significantly smaller than an area of the pixel circuit in FIG. 8, resulting in an effect of enabling implementation of an ultra-high resolution display device. Additionally, as some components are omitted, the power consumed by the pixel circuits in FIGS. 4 and 6 is less than the power consumed by the pixel circuit in FIG. 8.

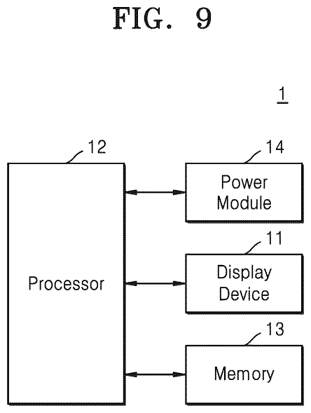

FIG. 9 is a block diagram of an electronic device.

Referring to FIG. 9, the electronic device 1 may comprise the display device 11, a processor 12, a memory 13, and a power module 14. The display device 11 may comprise the display panel 10 above mentioned.

The processor 12 may comprise at least one of a central processing unit (CPU), an application processor (AP), a graphic processing unit (GPU), a communication processor (CP), an image signal processor (ISP), and a controller.

Data for operations of the processor 12 or the display device 11 may be stored in the memory 13. When the processor 12 executes an application stored in the memory 13, image data signals and/or input control signals may be transferred to the display device 11, and the display device 11 may process the received signals to output image information through a display screen.

The power module 14 may comprise a power supply module such as a power adapter or a battery device, and a power conversion module that converts power supplied by the power supply module to generate power necessary for operation of the electronic device 1.

At least one of the components of the display device 11 described above may be comprised in the electronic device 1 to the embodiments described above. Additionally, some individual modules functionally comprised in one module may be comprised in the display device 11 while others may be provided separately from the display device 11.

The display device 11 of FIG. 9 may comprise one of the examples of the display panel 10 described in FIGS. 1 to 8. For convenience of description, other descriptions are omitted, but one of ordinary skill in the art can easily and clearly understand the display panel 10 comprised by the display device 11 of FIG. 9 based on the descriptions of FIGS. 1 to 8.

In an embodiment, the electronic device 1 may comprise the memory 13 which stores data information, the processor 12 which generates data signals and/or control signals based on the data information, and the display device 11 that operates based on the data signals and/or control signals.

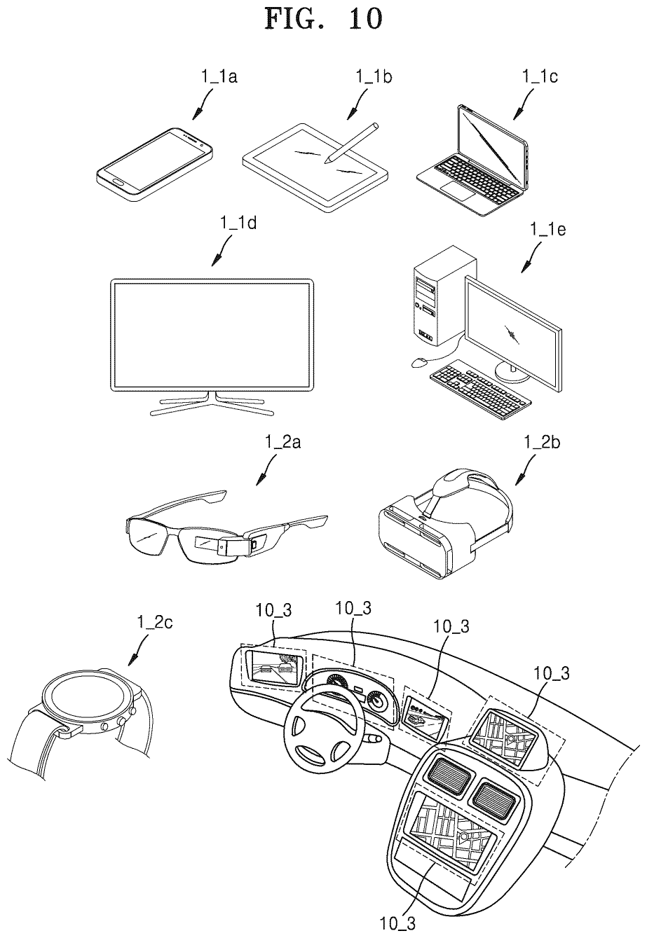

FIG. 10 shows schematic views of various electronic device.

Referring to FIG. 10, the electronic device 1 may comprise not only electronic devices for displaying image such as smartphone 1_1a, tablet PC 1_1b, laptop 1_1c, TV 1_1d, and desktop monitor 1_1e, but also wearable electronic devices comprising display modules such as smart glass 1_2a, head-mounted display 1_2b, and smart watch 1_2c, as well as vehicle electronic device 10_3 comprising display module such as instrument panel, center fascia, dashboard equipped with Center Information Display, and rearview mirror display of automobile.

As described above, according to some embodiments, a pixel circuit for implementing a slim bezel and a display device including the pixel circuit may be realized. Obviously, the scope of embodiments according to the present disclosure are not limited by the effects.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims, and their equivalents.

What is claimed is:

1. A pixel circuit comprising:
a light-emitting element;
a first switching element configured to control a driving current flowing through the light-emitting element and including an upper gate electrode, a lower gate electrode, and a semiconductor layer between the upper gate electrode and the lower gate electrode in a cross-sectional view of the pixel circuit;
a second switching element electrically connected to the lower gate electrode and configured to transmit a data signal to the lower gate electrode based on a data control signal; and
a storage capacitor including a first electrode electrically connected to the lower gate electrode and a second electrode electrically connected to one of source-drain electrodes of the first switching element.

2. The pixel circuit of claim 1, wherein the first switching element is further configured to turn on or off based on an emission control signal transmitted through the upper gate electrode.

3. The pixel circuit of claim 2, wherein a magnitude of the driving current corresponds to the data signal transmitted through the lower gate electrode.

4. The pixel circuit of claim 1, further comprising a third switching element electrically connected between the first electrode and a reference voltage line configured to transmit a reference voltage.

5. The pixel circuit of claim 1, wherein the light-emitting element includes an anode electrode electrically connected to the first switching element, and
the pixel circuit further comprises a fourth switching element electrically connected between the anode electrode and an initialization voltage line configured to transmit an initialization voltage.

6. The pixel circuit of claim 1, wherein the light-emitting element includes an anode electrode electrically connected to the first switching element, and
the pixel circuit further comprises a fifth switching element electrically connected between the anode electrode and the first switching element.

7. The pixel circuit of claim 6, wherein a semiconductor layer of the first switching element includes an oxide semiconductor.

8. The pixel circuit of claim 6, wherein a semiconductor layer of the fifth switching element includes low-temperature polysilicon.

9. The pixel circuit of claim 6, wherein the first electrode is a portion of the lower gate electrode.

10. The pixel circuit of claim 9, wherein the second electrode is a portion of a semiconductor layer of the fifth switching element.

11. The pixel circuit of claim 6, wherein a portion of the lower gate electrode and a portion of the semiconductor layer of the fifth switching element overlap in a plan view of the pixel circuit.

12. The pixel circuit of claim 11, wherein
the portion of the semiconductor layer of the fifth switching element is electrically connected to the one of the source-drain electrodes of the first switching element, and
another one of the source-drain electrodes of the first switching element is electrically connected to a power voltage line transmitting a power voltage.

13. The pixel circuit of claim 1, wherein
a first distance between an upper surface of the semiconductor layer of the first switching element and the upper gate electrode is less than a second distance between a lower surface of the semiconductor layer of the first switching element and the lower gate electrode.

14. A display device comprising:
a pixel circuit including a light-emitting element configured to emit light according to a data signal and a gate control signal;
a gate driver configured to generate the gate control signal;
a data driver configured to generate the data signal; and
a controller configured to control the gate driver and the data driver,
wherein the pixel circuit includes:
a first switching element configured to control a driving current flowing through the light-emitting element and including an upper gate electrode, a lower gate electrode, and a semiconductor layer between the upper gate electrode and the lower gate electrode in a cross-sectional view of the pixel circuit;
a second switching element electrically connected to the lower gate electrode and configured to transmit the data signal to the lower gate electrode based on a data control signal; and
a storage capacitor including a first electrode electrically connected to the lower gate electrode and a second electrode electrically connected to one of source-drain electrodes of the first switching element.

15. The display device of claim 14, wherein the first switching element is further configured to turn on or off based on an emission control signal transmitted through the upper gate electrode.

16. The display device of claim 15, wherein a magnitude of the driving current corresponds to the data signal transmitted through the lower gate electrode.

17. The display device of claim 14, wherein the light-emitting element includes an anode electrode electrically connected to the first switching element, and
the pixel circuit further comprises a fifth switching element electrically connected between the anode electrode and the first switching element.

18. The display device of claim 17, wherein the first electrode is a portion of the lower gate electrode.

19. The display device of claim 18, wherein the second electrode is a portion of a semiconductor layer of the fifth switching element.

20. An electronic device comprising:
a memory which stores data information;
a processor which generates data signals and/or control signals based on the data information; and
a display device which operates based on the data signals and/or the control signals, wherein the display device comprising:
a pixel circuit including a light-emitting element configured to emit light according to a data signal and a gate control signal;
a gate driver configured to generate the gate control signal;
a data driver configured to generate the data signal; and
a controller configured to control the gate driver and the data driver,
wherein the pixel circuit includes:
a first switching element configured to control a driving current flowing through the light-emitting element and including an upper gate electrode, a lower gate electrode, and a semiconductor layer between the upper gate electrode and the lower gate electrode in a cross-sectional view of the pixel circuit;
a second switching element electrically connected to the lower gate electrode and configured to transmit the data signal to the lower gate electrode based on a data control signal; and
a storage capacitor including a first electrode electrically connected to the lower gate electrode and a second electrode electrically connected to one of source-drain electrodes of the first switching element.
